(19) United States
(12) Patent Application Publication
(10) Pub. No.: US 2007/0164446 A1
(43) Pub. Date: Jul. 19, 2007

(54) Integrated circuit having second substrate to facilitate core power and ground distribution

(76) Inventors: Donald E. Hawk JR., King of Prussia, PA (US); James C. Parker, Upper Milford Township, PA (US)

Correspondence Address: Ryan, Mason & Lewis, LLP, 90 Forest Avenue, Locust Valley, NY, 11560, US

(21) Appl. No.: 11/332,040

(22) Filed: Jan. 13, 2006

(51) Int. Cl. H01L 23/48

(52) U.S. Cl. 257/778

(57) ABSTRACT

An integrated circuit comprises a first substrate, an integrated circuit die attached to the first substrate, and a second substrate overlying at least a portion of the integrated circuit die. The second substrate comprises at least one conductor that is wire bonded to a conductor of the first substrate and electrically connected to a conductor of the integrated circuit die. In an illustrative embodiment, conductors of the second substrate are used to provide core power and ground connections for the integrated circuit die.

### FIELD OF THE INVENTION

The present invention relates generally to integrated circuits, and more particularly to distribution of power, ground or other signal lines within a packaged integrated circuit.

### BACKGROUND OF THE INVENTION

A wide variety of different integrated circuit package types are known in the art. One package type, referred to as a wire bond package, typically utilizes wire bonds to connect the leads of a lead frame or other type of substrate with corresponding bond pads on an integrated circuit die. Packages of this type may utilize a plastic ball grid array (PBGA) substrate, and thus may be referred to as wire bond PBGA packages.

Although such a package has the advantage of low cost, it may be unable to deliver the necessary power to the core of the integrated circuit die, particularly in high power applications, without experiencing a significant voltage drop through the power and ground conductors. Accordingly, flip-chip packages are often used in such high power applications. However, flip-chip packages can be very expensive due to factors such as the fine line routing typically used in the package substrate. Although the cost of the flip-chip package can be reduced by using coarser line routing in the substrate, the resulting package may not be able to accommodate the desired number of signals per unit edge.

Many different stacked-die integrated circuit configurations are also known. These include, by way of example, the arrangements described in U.S. Patent Application Publication No. 2002/0074637, entitled “Stacked Flip Chip Assemblies,” U.S. Patent Application Publication No. 2005/0194674, entitled “Integrated Circuit with Re-Route Layer and Stacked Die Assembly,” and PCT International Application No. WO 2005/034238 entitled “Electrical Shielding in Stacked Dies by Using Conductive Die Attach Adhesive.”

U.S. patent application Ser. No. 11/010,721, filed Dec. 13, 2004 in the name of inventor Thaddeus J. Gabara and entitled “Integrated Circuit with Stacked-Die Configuration Utilizing Substrate Conduction,” which is commonly assigned herewith and incorporated by reference herein, discloses techniques for providing substrate conduction in an integrated circuit having a stacked-die configuration. In one arrangement disclosed therein, an integrated circuit comprises a plurality of integrated circuit die arranged in a stack, with a given die other than a top die of the stack carrying current for itself and at least one additional die of the stack via substrate conduction.

Although stacked-die arrangements of the type described in the above-cited references can provide numerous advantages over single-die integrated circuits, such arrangements generally do not adequately address the above-noted core power and ground distribution problems of wire bond PBGA packages and other types of conventional wire bond packages.

Accordingly, what is needed is an improved integrated circuit packaging arrangement which can accommodate high power applications without the significant voltage drop of conventional wire bond packages and without the costs associated with the fine line routing of typical flip-chip packages.

### SUMMARY OF THE INVENTION

Illustrative embodiments of the invention provide improved packaging arrangements in which an additional substrate, overlying an integrated circuit die attached to a package substrate, is used to facilitate core power and ground distribution.

In accordance with an aspect of the invention, an integrated circuit comprises a first substrate, an integrated circuit die attached to the first substrate, and a second substrate overlying at least a portion of the integrated circuit die. The second substrate comprises at least one conductor that is wire bonded to a conductor of the first substrate and electrically connected to a conductor of the integrated circuit die.

In one of the illustrative embodiments, conductors of the second substrate are used to provide core power and ground connections for the integrated circuit die. More specifically, the second substrate may comprise a plurality of conductors on an upper surface of the second substrate, a plurality of conductors on a lower surface of the second substrate, and a plurality of vias passing through the second substrate from its upper surface to its lower surface. Each of the vias provides an electrical connection between one or more of the upper surface conductors of the second substrate and one or more of the lower surface conductors of the second substrate. The upper surface conductors of the second substrate are wire bonded to respective conductors of the first substrate, and the lower surface conductors of the second substrate are electrically connected to respective conductors of the integrated circuit die via respective solder bumps or other suitable types of substrate-to-die interconnects.

In accordance with another aspect of the invention, a method of forming an integrated circuit is provided. The method includes the steps of attaching an integrated circuit die to a first substrate, providing a second substrate overlying at least a portion of the integrated circuit die, and wire bonding at least one conductor of the second substrate to a conductor of the first substrate, where the conductor of the second substrate is electrically connected to a conductor of the integrated circuit die. The second substrate may be connected to the integrated circuit die before the die is attached to the first substrate, for example, at the wafer level. Alternatively, the second substrate may be connected to the integrated circuit die after the die is attached to the first substrate.

The illustrative embodiments provide a number of significant advantages over the conventional techniques previously described. For example, these embodiments overcome the above-noted core power and ground distribution problems of wire bond PBGA packages and other types of conventional wire bond packages. They can accommodate high power applications without the significant voltage drop of conventional wire bond packages and without the costs associated with typical flip-chip packages having fine line routing.

### BRIEF DESCRIPTION OF THE DRAWINGS

FIG. 1 is a side cross-sectional view of a packaged integrated circuit utilizing a wire bond package configured in accordance with a first illustrative embodiment of the invention.

FIG. 2 is perspective view of an exposed portion of a packaged integrated circuit in a second illustrative embodiment of the invention, utilizing a wire bond package similar to the type shown in FIG. 1.

### DETAILED DESCRIPTION OF THE INVENTION

The present invention will be illustrated herein in the context of a number of exemplary integrated circuits, and associated packaging arrangements. It should be understood, however, that the particular integrated circuits and packaging arrangements shown are provided by way of illustrative example only, and not intended to limit the scope of the invention in any way. As will become apparent, the techniques of the invention are utilizable in a wide variety of other integrated circuit configurations in which it is desirable to provide improvements relative to conventional wire bond and flip-chip packages.

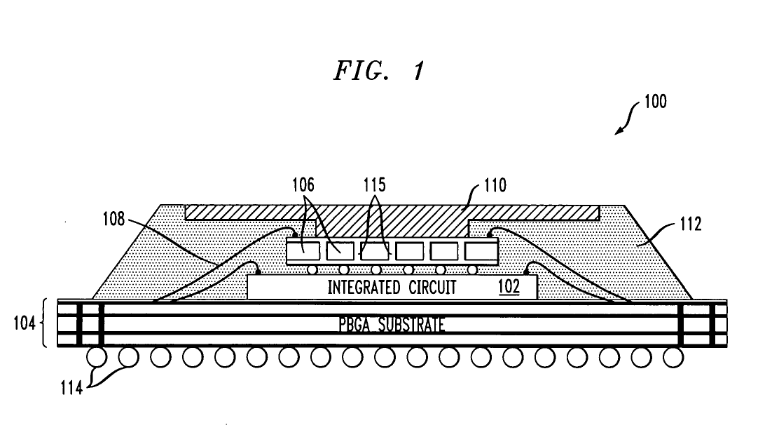

FIG. 1 shows a packaged integrated circuit 100 configured in accordance with a first illustrative embodiment of the invention. The integrated circuit 100 comprises an integrated circuit die 102, a first substrate 104 and a second substrate 106. The integrated circuit die 102 is attached to the first substrate 104 using conventional die attach techniques. The second substrate 106 overlies the integrated circuit die 102 as shown. Generally, the second substrate 106 comprises at least one conductor that is wire bonded to a conductor of the first substrate 104 and electrically connected to a conductor of the integrated circuit die 102. In this particular embodiment, conductors of the second substrate 106 are used to provide core power and ground connections between the first substrate 104 and the integrated circuit die 102, as will be described in greater detail below.

The first substrate 104 in this embodiment comprises a ball grid array substrate, or more specifically a PBGA substrate, while the second substrate 106 comprises a flip-chip substrate. It should be understood, however, that other types of substrates, in any combination, may be used in other embodiments.

The integrated circuit 100 further comprises a heat spreader 110 that is attached to an upper surface of the second substrate 106 and configured to facilitate dissipation of heat from the integrated circuit die 102. The heat spreader may be formed of metal or other suitable materials, using conventional techniques, as will be appreciated by those skilled in the art. In other embodiments, the heat spreader may be eliminated.

The integrated circuit 100 in this embodiment comprises a packaged integrated circuit which utilizes a wire bond type package. Wire bonds 108 are utilized to connect conductors of the first substrate 104 with upper surface conductors of the integrated circuit die 102. Additional wire bonds 108 are used to connect conductors of the first substrate 104 with upper surface conductors of the second substrate 106. In this illustrative embodiment, these latter conductors are power and ground conductors utilized to supply core power and ground to the integrated circuit die 102 from the first substrate 104. The term “power” as used in this context may refer, for example, to a VDD power supply, a VSS power supply, or other positive or negative supply voltage, without limitation.

The integrated circuit 100 is encapsulated using a conventional encapsulating material 112, such as plastic, to form a packaged integrated circuit. In this exemplary packaging arrangement, the lower surface of the first substrate 104 comprises a plurality of solder balls or other types of connectors 114 to facilitate installation of the packaged integrated circuit on a circuit board or other mounting structure. These and other conventional aspects of a wire bond type packaged integrated are well understood in the art, and therefore will not be further described herein.

The second substrate 106 in this embodiment comprises a plurality of conductors on its upper surface, a plurality of conductors on its lower surface, and a plurality of vias 115 passing through the second substrate from its upper surface to its lower surface. Each of the vias provides an electrical connection between one or more of the upper surface conductors of the second substrate and one or more of the lower surface conductors of the second substrate. As indicated above, upper surface conductors of the second substrate 106 are wire bonded to respective conductors of the first substrate 104. Lower surface conductors of the second substrate 106 are electrically connected to respective conductors of the integrated circuit die 102 via respective solder bumps or other suitable types of substrate-to-die interconnects.

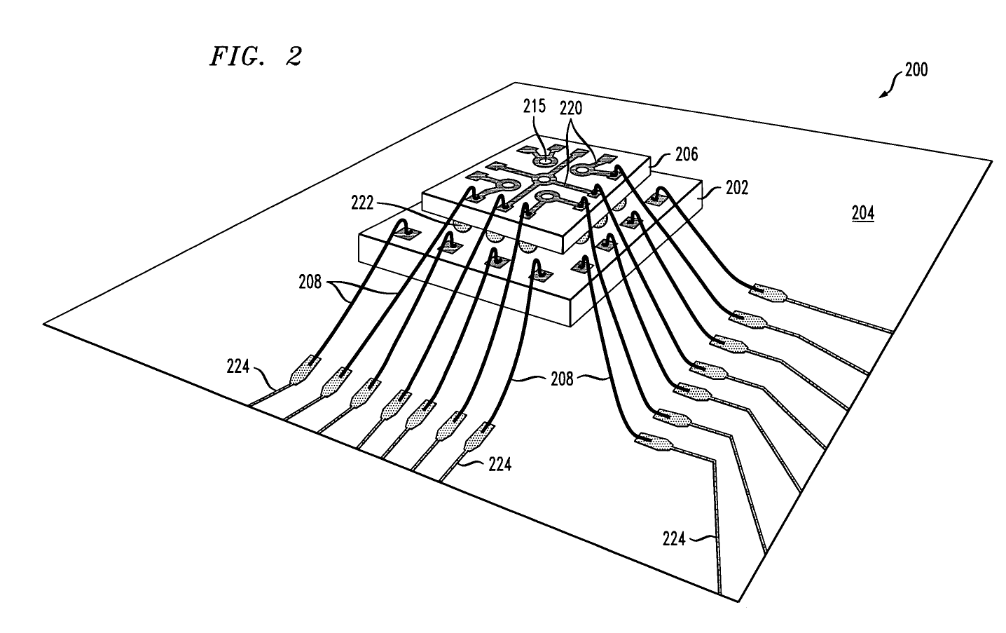

FIG. 2 shows another embodiment of the invention, in the form of an integrated circuit 200. This embodiment is similar to the FIG. 1 embodiment, but has a different configuration of the first and second substrates. A perspective view is provided in this figure rather than the side cross-sectional view of FIG. 1 in order to better show features such as the upper surface conductors of the first and second substrates and the integrated circuit die. Also, the heat spreader and encapsulating material are omitted from this view for simplicity and clarity of illustration.

The integrated circuit 200 comprises an integrated circuit die 202 attached to a first substrate 204. A second substrate 206 overlies the integrated circuit die. The upper surface of the second substrate comprises conductors 220 that are coupled to vias 215 which pass through the second substrate 206 to its lower surface. At the lower surface, the vias 215 are coupled to lower surface conductors (not shown) of the second substrate 206. These lower surface conductors are coupled via interconnects 222, which illustratively comprise solder bumps, to corresponding conductors (not shown) on an upper surface of the integrated circuit die 202.

The first substrate 204 includes peripheral conductors 224 that are wire bonded to corresponding conductors on the second substrate 206 or integrated circuit die 202. More specifically, certain peripheral conductors 224 of the first substrate 204 are wire bonded to corresponding peripheral conductors of the integrated circuit die 202, while other peripheral conductors 224 of the first substrate 204 are wire bonded to corresponding peripheral conductors of the second substrate 206. The wire bonding in this embodiment occurs at bond pads that are associated with the respective conductors, although the term “conductor” as used herein is intended to be construed generally so as to encompass bond pads, conductive traces, solder balls or other interconnects, or similar conductive circuit elements, in any combination.

With regard to the bond pads, it can be seen that the integrated circuit die 202 has an upper surface having a plurality of bond pads arranged adjacent a periphery of the upper surface. The integrated circuit die may further comprise a plurality of bond pads or other types of conductors arranged in a central region of the upper surface, although such conductors are not shown in the figure for simplicity and clarity of illustration. The second substrate 206 overlies the central region of the upper surface of the integrated circuit die 202 and has lower surface conductors in electrical contact with the bond pads or other conductors of the central region of the integrated circuit die 202. In this embodiment, the second substrate 206 overlies the central region of the upper surface of the integrated circuit die in such a manner that it does not extend past any peripheral edge of the upper surface of the integrated circuit die. Also, the second substrate 206 is substantially centered between opposing peripheral edges of the upper surface of the integrated circuit die 202. However, it is to be appreciated that numerous alternative arrangements for stacking the first substrate, integrated circuit die and second substrate may be used. For example, the second substrate may extend over one or more edges of the underlying integrated circuit die. In these and other arrangements, it is contemplated that there is at least partial overlap between the second substrate and the integrated circuit die. Also, a given stack may include multiple additional substrates, alternating die and substrates, or a wide variety of other stacking arrangements. It is therefore to be appreciated that the present invention is not limited to a single substrate-die-substrate stack or any other particular stacking arrangement.

As in the previous embodiment, the conductors associated with the second substrate 206 are used to supply power and ground connections to the integrated circuit die 202. Thus, the adjacent peripheral conductors of the first substrate 204 may have respective widths which are substantially less than those of the adjacent peripheral conductors of the second substrate 206. Also, the adjacent peripheral conductors of the first substrate 204 may be separated by a pitch which is substantially less than a pitch of adjacent peripheral conductors of the second substrate 206. Such width and pitch arrangements are not explicitly shown in the simplified figure, and should not be viewed as requirements of the invention.

The embodiments described above provide a number of significant advantages relative to conventional practice. For example, these improved integrated circuit packaging arrangements overcome the above-noted core power and ground distribution problems of wire bond PBGA packages and other types of conventional wire bond packages. They can accommodate high power applications without the significant voltage drop of conventional wire bond packages and without the costs associated with typical flip-chip packages. The second substrate 106 or 206 can be a reduced-cost flip-chip type of substrate, since only coarse line routing is needed for power and ground distribution. The first substrate 104 or 204 may be an inexpensive PBGA substrate which provides a high number of signals per unit edge.

Also, the stacked arrangement of first substrate, integrated circuit die, and second substrate in the illustrative embodiments provides a three-dimensional separation of the wire bonds which allows power supply and ground conductors to be better isolated from input-output (IO) signal lines.

In addition, the conductors of the second substrate may be formed as relatively thick metal structures which can deliver the needed core power to the integrated circuit die, particularly in high power applications, without experiencing the significant voltage drop which might result from conventional interconnections.

Moreover, the illustrative embodiments conserve area resources on the integrated circuit die, because it is no longer necessary to bring core power and ground through a conventional IO ring on the integrated circuit die. This may lead to reduced die sizes in pad limited situations.

Furthermore, reducing the integrated circuit metal resources required to deliver core power and ground can result in lower integrated circuit costs by, for example, increasing the routing density in the core, reducing the number of metal layers in the integrated circuit, etc.

Although used in the illustrative embodiments for core power and ground distribution, the second substrate can be used to distribute other types of signals from the package substrate to the integrated circuit die, and the invention is not limited in this regard.

It should be noted that the particular configurations shown in FIGS. 1 and 2 are presented by way of illustrative example only, and should not be construed as limiting the scope of the invention in any way. Also, certain conventional elements have been omitted from the figures for clarity and simplicity of illustration. Such omitted elements may be included in a given embodiment of the invention, as will be appreciated by those skilled in the art.

An alternative embodiment of the invention may comprise, for example, multiple additional substrates each overlying a different portion of the upper surface of the integrated circuit die.

It is also possible to have multiple integrated circuit die in a single packaged integrated circuit, with each such die having at least one additional substrate overlying at least a portion thereof in the manner described herein.

As indicated above, a given embodiment of the present invention may comprise one or more integrated circuit die. In such an arrangement, a plurality of identical die is typically formed in a repeated pattern on a surface of a wafer. Each die may include a variety of structures or circuits. The individual die are cut or diced from the wafer, then packaged as an integrated circuit. One skilled in the art would know how to dice wafers and package die to produce integrated circuits. Integrated circuits so manufactured are considered part of this invention.

In manufacturing an integrated circuit in accordance with one of the embodiments described above, it may be preferable to connect the overlying substrate 106 or 206 to the respective integrated circuit die 102 or 202 at the wafer level, before the die is attached to the package substrate 104 or 204. For example, if solder bumps are used to provide the interconnection between the overlying substrate and the integrated circuit die, one may not want to subject the package substrate to the solder reflow operations required to establish electrical connection between conductors of the overlying substrate and corresponding conductors of the integrated circuit die. After the overlying substrates are attached to the respective die at the wafer level, the wafer is cut or diced and the resulting devices, each comprising a die plus an overlying substrate, are attached to package substrates using conventional techniques and then wire bonded as described previously herein. It is also possible to connect the overlying substrate to the integrated circuit die after the die has been attached to the package substrate.

Again, the above-described embodiments of the invention are intended to be illustrative only. Numerous alternative embodiments may be devised by those skilled in the art without departing from the scope of the following claims. For example, numerous alternative configurations of integrated circuit elements such as substrates, dies, wire bonds, bond pads, stacking arrangements or package types can be used. Also, a wide variety of alternative process steps may be used to form an integrated circuit in accordance with the invention. These and other alternative embodiments will be readily apparent to those skilled in the art.

What is claimed is:

1. An integrated circuit comprising:
a first substrate;
an integrated circuit die attached to the first substrate; and
a second substrate overlying at least a portion of the integrated circuit die;
the second substrate comprising at least one conductor that is wire bonded to a conductor of the first substrate and electrically connected to a conductor of the integrated circuit die.

2. The integrated circuit of claim 1 wherein the first substrate comprises a ball grid array substrate.

3. The integrated circuit of claim 1 wherein the second substrate comprises a flip-chip substrate.

4. The integrated circuit of claim 1 wherein the second substrate comprises a plurality of conductors on an upper surface of the second substrate, a plurality of conductors on a lower surface of the second substrate, and a plurality of vias passing through the second substrate from its upper surface to its lower surface, each of said vias providing an electrical connection between one or more of the upper surface conductors of the second substrate and one or more of the lower surface conductors of the second substrate.

5. The integrated circuit of claim 4 wherein multiple ones of the upper surface conductors of the second substrate are wire bonded to respective conductors of the first substrate.

6. The integrated circuit of claim 4 wherein multiple ones of the lower surface conductors of the second substrate are electrically connected to respective conductors of the integrated circuit die.

7. The integrated circuit of claim 6 wherein the multiple ones of the lower surface conductors of the second substrate are electrically connected to the respective conductors of the integrated circuit die via respective solder bumps.

8. The integrated circuit of claim 1 wherein the conductor of the second substrate that is wire bonded to the conductor of the first substrate and electrically connected to the conductor of the integrated circuit die comprises a power supply conductor configured to provide a power supply connection between the integrated circuit die and the first substrate.

9. The integrated circuit of claim 1 wherein the conductor of the second substrate that is wire bonded to the conductor of the first substrate and electrically connected to the conductor of the integrated circuit die comprises a ground conductor configured to provide a ground connection between the integrated circuit die and the first substrate.

10. The integrated circuit of claim 1 wherein the integrated circuit die has an upper surface having a plurality of bond pads arranged adjacent a periphery of the upper surface and a plurality of conductors arranged in a central region of the upper surface, the second substrate overlying the central region of the upper surface of the integrated circuit die and having conductors in electrical contact with the conductors of the central region.

11. The integrated circuit of claim 1 wherein power and ground connections between the first substrate and the integrated circuit die are made via the second substrate.

12. The integrated circuit of claim 1 wherein two or more peripheral conductors of the first substrate have respective widths which are less than those of two or more peripheral conductors of the second substrate.

13. The integrated circuit of claim 1 wherein a first peripheral conductor of the first substrate is wire bonded to a first peripheral conductor of the integrated circuit die and a second peripheral conductor of the first substrate is wire bonded to a first peripheral conductor of the second substrate.

14. The integrated circuit of claim 1 further comprising a heat spreader attached to an upper surface of the second substrate and configured to facilitate dissipation of heat from the integrated circuit die.

15. The integrated circuit of claim 1 wherein the second substrate overlies a central region of an upper surface of the integrated circuit die and does not extend past any peripheral edge of the upper surface of the integrated circuit die.

16. The integrated circuit of claim 1 wherein the second substrate is substantially centered between opposing peripheral edges of an upper surface of the integrated circuit die.

17. The integrated circuit of claim 1 wherein the integrated circuit is encapsulated to form a packaged integrated circuit.

18. The integrated circuit of claim 1 wherein the integrated circuit is packaged in a wire bond plastic ball grid array package.

19. An integrated circuit comprising:
an integrated die coupled between first and second substrates;
the first substrate comprising a ball grid array substrate supporting the integrated circuit die and wire bonded to the integrated circuit die and the second substrate;
the second substrate comprising a flip-chip substrate overlying and in electrical contact with the integrated circuit die.

20. A method of forming an integrated circuit, the method comprising the steps of:
attaching an integrated circuit die to a first substrate;
providing a second substrate overlying at least a portion of the integrated circuit die; and
wire bonding at least one conductor of the second substrate to a conductor of the first substrate, said conductor of the second substrate also being electrically connected to a conductor of the integrated circuit die.

21. The method of claim 20 wherein the second substrate is connected to the integrated circuit die before said die is attached to said first substrate.
